(19) United States
(12) Patent Application Publication
(10) Pub. No.: US 2026/0080957 A1
(43) Pub. Date: Mar. 19, 2026

(54) MEMORY DEVICE AND METHOD OF OPERATING THE SAME

(71) Applicant: SK hynix Inc., Gyeonggi-do (KR)

(72) Inventors: Yun Su KIM, Gyeonggi-do (KR); Da Won KIM, Gyeonggi-do (KR); Han Soo JOO, Gyeonggi-do (KR)

(21) Appl. No.: 19/095,042

(22) Filed: Mar. 31, 2025

(30) Foreign Application Priority Data
Sep. 19, 2024 (KR) 10-2024-0126522

(51) Int. Cl. G11C 16/34; G11C 16/04; G11C 16/08; G11C 16/10

(52) U.S. Cl. CPC G11C 16/3427; G11C 16/0483; G11C 16/08; G11C 16/10

(57) ABSTRACT

Provided herein may be a memory device. The memory device may include a memory block configured to include a first selection line, word lines, a second selection line, a channel layer, first select transistors, second select transistors, and memory cells; a voltage generator configured to generate a turn-on voltage and a turn-off voltage to be applied to the first and second selection lines, and generate a program voltage and a pass voltage to be applied to word lines; a source line driver configured to generate a precharge voltage to be applied to the source line; a page buffer group configured to apply a program-enable voltage and a program-inhibit voltage to bit lines; and a control circuit configured to determine a reference position and control the voltage generator, the source line driver, and the page buffer group to adjust time required to precharge the channel layer.

### CROSS-REFERENCE TO RELATED APPLICATION

The present application claims priority under 35 U.S.C. § 119(a) to Korean patent application number 10-2024-0126522, filed on Sep. 19, 2024, in the Korean Intellectual Property Office, the entire disclosure of which is incorporated herein by reference.

### BACKGROUND

### 1. Field of Invention

Various embodiments of the present disclosure relate to a memory device and a method of operating the memory device.

### 2. Description of Related Art

A memory device may include a memory cell array, a peripheral circuit, and a control circuit. The memory cell array may include memory blocks, each of which may include memory cells in which data is stored. The peripheral circuit may program, read, or erase the memory cells under control of the control circuit. The control circuit may control the peripheral circuit to perform a program operation, a read operation, or an erase operation in response to a corresponding command.

Each memory block may be implemented in a two-dimensional (2D) structure or a three-dimensional (3D) structure depending on the array structure of memory cells.

In a memory block implemented in the 2D structure, memory cells may be arranged in a direction horizontal to a substrate. Therefore, the area of the memory block implemented in the 2D structure increases as the number of memory cells increases.

In a memory block implemented in the 3D structure, memory cells may be arranged in a direction horizontal to a substrate, and may also be stacked in a direction vertical to the substrate. Therefore, the memory block implemented in the 3D structure may include more memory cells than those in the memory block implemented in the 2D structure.

In a memory block implemented in the 3D structure, the memory cells may be stacked along a plug extending in the direction vertical to the substrate. The plug may include a channel layer and a charge trap layer that extend in the vertical direction.

Due to characteristics of a process of manufacturing the memory device, the width of the plug may taper (e.g., become smaller) in a downward direction. Therefore, electrical characteristics of the memory cells may vary depending on the positions of the memory cells. For example, disturbances may occur where the threshold voltages of unselected memory cells are changed during a program operation performed on selected memory cells. These disturbances may occur more frequently as the size of the memory cells is reduced. Due to such disturbances, the reliability of the memory device may be adversely affected.

### SUMMARY

Various embodiments of the present disclosure are directed to a memory device and a method of operating the memory device, which can prevent disturbances from occurring in unselected memory cells by adjusting the time required to precharge a channel layer depending on the size of selected memory cells during a program operation for the selected memory cells.

An embodiment of the present disclosure may provide for a memory device. The memory device may include a memory block including include a first selection line, word lines, and a second selection line that are stacked between a source line and bit lines, a channel layer penetrating the first selection line, the word lines, and the second selection line, first select transistors connected to the first selection line, second select transistors connected to the second selection line, and memory cells connected to the word lines. The first select transistors, the second select transistors, and the memory cells are stacked along the channel layer.

The memory device further includes a voltage generator configured to generate a turn-on voltage and a turn-off voltage to be applied to the first and second selection lines, and generate a program voltage and a pass voltage to be applied to the word lines. The memory device further includes a source line driver configured to generate a precharge voltage to be applied to the source line, a page buffer group configured to apply a program-enable voltage and a program-inhibit voltage to the bit lines, and a control circuit. The control circuit is configured to determine a reference position for distinguishing a first area from a second area, the first area including word lines coupled to memory cells that may be affected by a disturbance, and the second area including word lines coupled to memory cells that may not be affected by the disturbance in the memory block. The control circuit if further configured to control the voltage generator, the source line driver, and the page buffer group to adjust a time required to precharge the channel layer depending on a result of a comparison between a position of a selected word line among the word lines and the reference position during a program operation performed for a memory cell that is coupled to the selected word line on the memory block.

An embodiment of the present disclosure may provide for a method of operating a memory device. The method may include dividing a plurality of word lines stacked between a source line and bit lines into a first group and a second group depending on a width of a plug penetrating the word lines, wherein the width of the plug corresponding to word lines included in the second group is smaller than the width of the plug corresponding to word lines included in the first group, precharging a channel layer included in the plug, after precharging the channel layer, applying a pass voltage to the word lines, and after the pass voltage is applied to the word lines, applying a program voltage to a selected word line from among the word lines. When the selected word line is included in the second group, precharging the channel layer is performed during a first time. When the selected word line is included in the first group, precharging the channel layer is performed during a second time shorter than the first time.

### BRIEF DESCRIPTION OF THE DRAWINGS

FIG. 1 is a diagram illustrating a memory system according to an embodiment of the present disclosure.

FIG. 2 is a diagram schematically illustrating a memory device according to an embodiment of the present disclosure.

FIG. 3 is a diagram illustrating in detail a memory device according an embodiment of the present disclosure.

FIG. 4 is a diagram illustrating a memory cell array according an embodiment of the present disclosure.

FIG. 5 is a circuit diagram illustrating a memory block according an embodiment of the present disclosure.

FIG. 6 is a sectional view illustrating the structure of a string according an embodiment of the present disclosure.

FIG. 7 is a plan view illustrating the structure of a string according an embodiment of the present disclosure.

FIG. 8 is a diagram illustrating a path through which operating voltages are transmitted according an embodiment of the present disclosure.

FIGS. 9A and 9B are diagrams illustrating word line groups according to an embodiment of the present disclosure.

FIGS. 10A and 10B are diagrams illustrating a program method according to a first embodiment of the present disclosure.

FIGS. 11A and 11B are diagrams illustrating a program method according to a second embodiment of the present disclosure.

FIG. 12 is a diagram illustrating word line groups according to an embodiment of the present disclosure.

FIGS. 13A to 13C are diagrams illustrating a program method according to a third embodiment of the present disclosure.

FIGS. 14A to 14C are diagrams illustrating a program method according to a fourth embodiment of the present disclosure.

FIG. 15 is a diagram illustrating a memory card system to which a memory device according to an embodiment of the present disclosure is applied.

FIG. 16 is a diagram illustrating a solid state drive (SSD) system to which a memory device according to an embodiment of the present disclosure is applied.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments described below, and may be modified in various forms and replaced with other equivalent embodiments.

Hereinafter, although the terms “first” and “second” may be used herein to describe various elements, these elements should not be limited by these terms. The terms are used to distinguish one element from other elements.

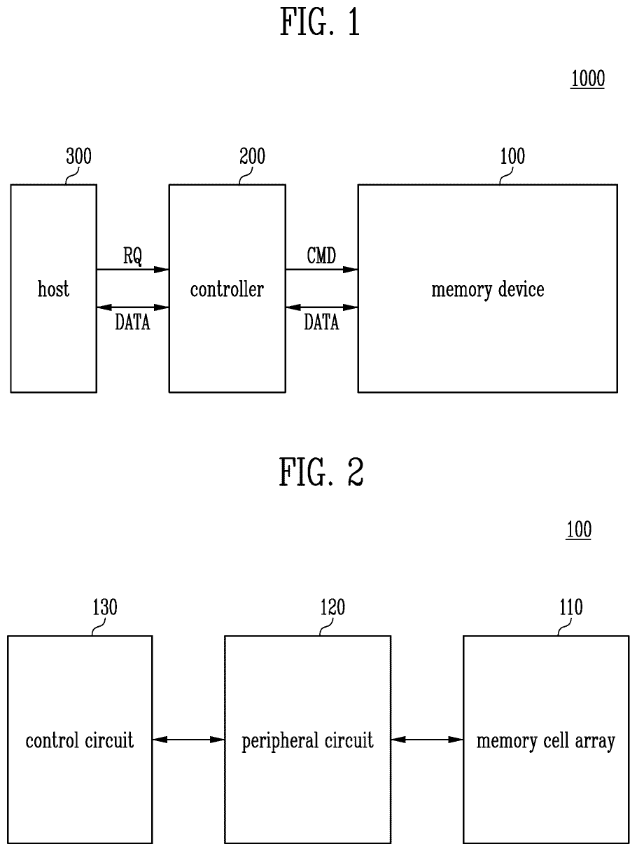

FIG. 1 is a diagram illustrating a memory system 1000 according to an embodiment of the present disclosure.

Referring to FIG. 1, the memory system 1000 may include a memory device 100, a controller 200, and a host 300. The memory device 100 may store data. The memory device 100 may be implemented as a nonvolatile memory device. The nonvolatile memory device may be a device in which stored data is retained even when power supply is interrupted.

The controller 200 may perform communication between the host 300 and the memory device 100. The controller 200 may control the memory device 100 in response to a request received from the host 300. For example, when a request RQ for a program operation is received from the host 300, the controller 200 may generate a command CMD corresponding to the program operation and transmit the command CMD to the memory device 100.

When a request RQ for a read operation is received from the host 300, the controller 200 may generate a command CMD corresponding to the read operation and transmit the command CMD to the memory device 100. During the read operation, when data DATA read from the memory device 100 is output, the controller 200 may perform an error correction operation on the read data DATA. In the error correction operation, the read data DATA may be decoded on a chunk basis.

The host 300 may communicate with the memory device 100 through the controller 200 using an interface protocol such as peripheral component interconnect-express (PCI-e or PCIe), advanced technology attachment (ATA), serial ATA (SATA), parallel ATA (PATA), or serial attached SCSI (SAS). The interface protocol is not limited to the above-described examples, and may include various interfaces, such as universal serial bus (USB), multi-media card (MMC), enhanced small disk Interface (ESDI), or integrated drive electronics (IDE).

When the host 300 transmits, to the controller 200, data DATA, together with the request RQ corresponding to a program operation for one or more selected memory cells, the controller 200 may generate a command CMD corresponding to the program operation in response to the request RQ for the program operation. The command CMD, corresponding to the program operation, and the data DATA may be transmitted to the memory device 100, and the memory device 100 may program the data DATA in the one or more selected memory cells in response to the command CMD.

In order to shorten the time required for performing the program operation and to prevent disturbances from occurring that may adversely affect performance of the memory system 1000, the memory device 100 according to the present embodiment may adjust the time required for channel precharging depending on the size of memory cells included in a selected page in a selected memory block, for the program operation. Disturbances that may occur during the program operation include those where the threshold voltages of unselected memory cells are affected by performance of the program operation on one or more selected memory cells. Therefore, as this disturbance is suppressed, the reliability of the memory device may be increased.

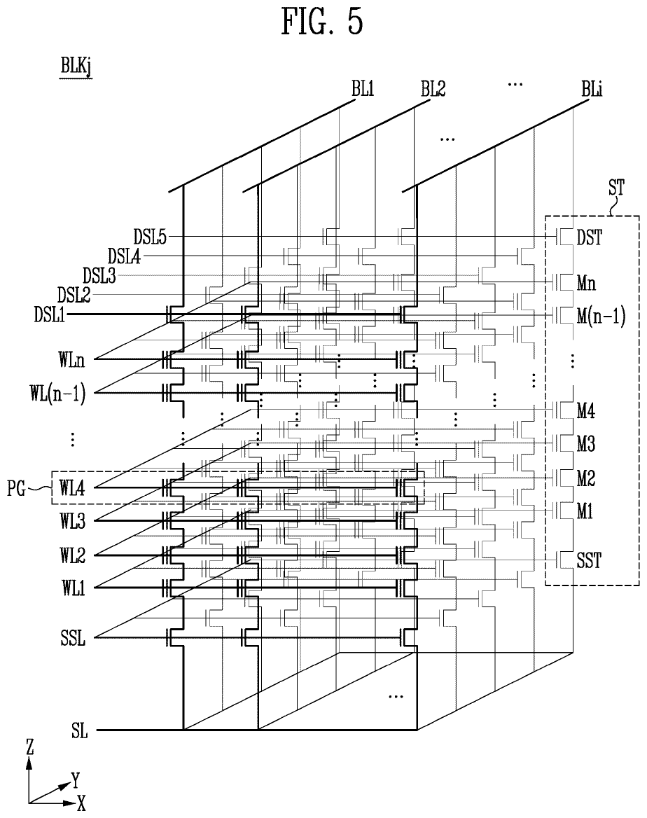

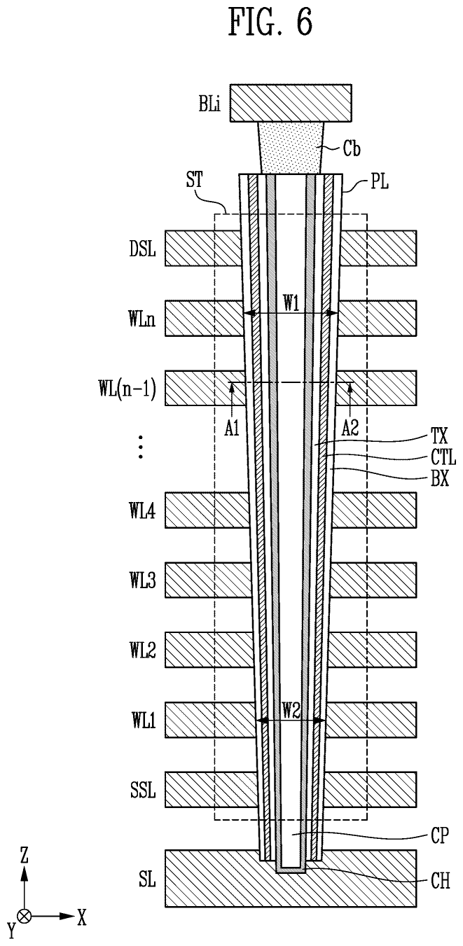

Each page may include a group of memory cells connected to the same word line among word lines included in the memory block. Therefore, different pages (e.g., see PG in FIG. 5) included in the same memory block may be located at different heights relative to a channel, as shown, for example, in FIG. 6, to be discussed in greater detail below. The size of memory cells may vary depending on the location of the page (and thus a position of the word lines) relative to a reference position. As the size of the memory cells become smaller, the size (e.g., width) of the channel provided for the memory cells may also be smaller. In the program operation according to the present embodiment, the program operation may be set such that, as the size of memory cells is smaller, a channel precharge time during a channel precharge phase becomes longer. Thus, the channel precharge time is inversely proportional to the size of the memory cells.

A channel precharge phase (period) may be a phase performed before a pass voltage is applied to word lines. In the channel precharge phase, a positive precharge voltage may be applied to the channels. The program operation may be set such that, as the size of the memory cells included in the selected page (or word line) is larger, the channel precharge time becomes shorter.

Therefore, according to the present embodiment, in a program operation performed on a page having larger memory cells, the channel precharge time may be shortened, and in a program operation performed on a page having smaller memory cells, the channel precharge time may be longer and thus disturbances caused by the precharge operation may be suppressed.

FIG. 2 is a diagram schematically illustrating the memory device 100 according to an embodiment of the present disclosure.

Referring to FIG. 2, the memory device 100 may include a memory cell array 110, a peripheral circuit 120, and a control circuit 130. The memory cell array 110 may store data. The peripheral circuit 120 may perform a program operation, a read operation, or an erase operation under the control of the control circuit 130. The control circuit 130 may control the peripheral circuit 120 in response to a command CMD output from a controller (e.g., 200 of FIG. 1). For example, the peripheral circuit 120 may receive data from the controller 200 and program the received data to a selected memory block of the memory cell array 110, under the control of the control circuit 130.

A program operation performed on the selected memory block may be performed on a page basis. When a selected page (or selected word line) is located above a reference position, the control circuit 130 may control the peripheral circuit 120 to shorten the time required to precharge a channel layer. When a selected page is located below the reference position, the control circuit 130 may control the peripheral circuit 120 to lengthen the time required to precharge the channel layer.

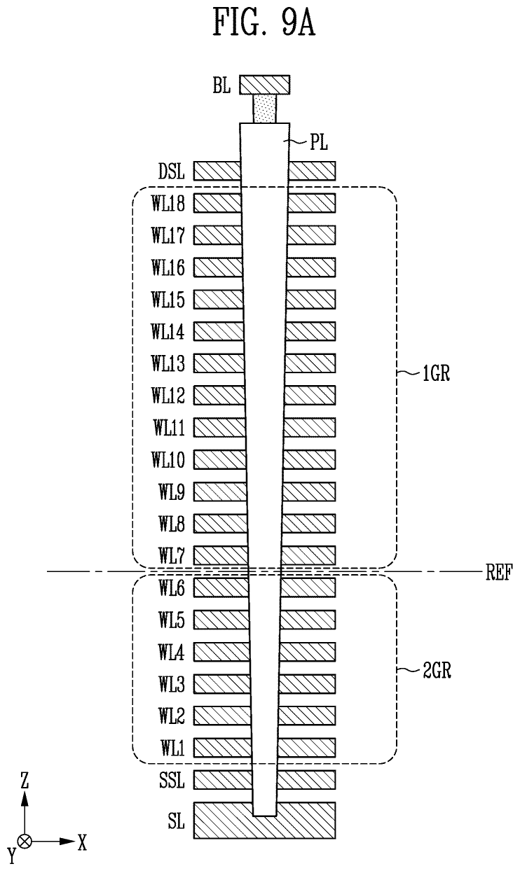

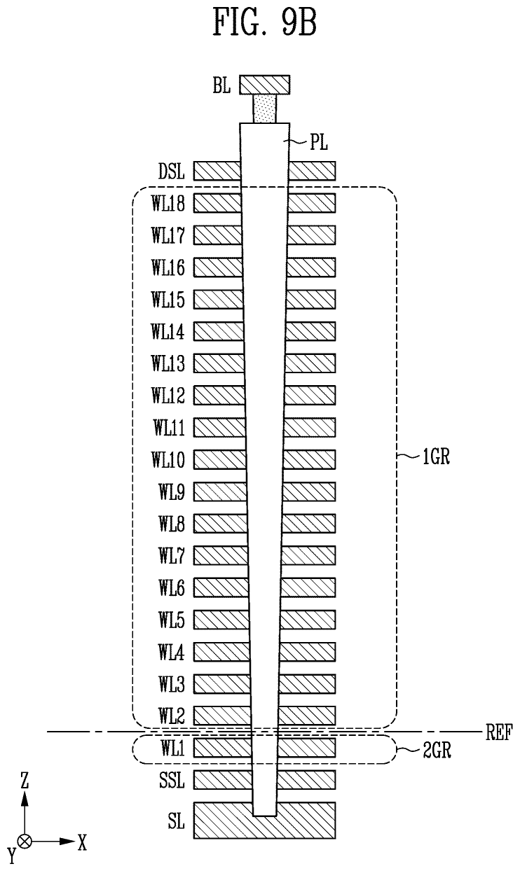

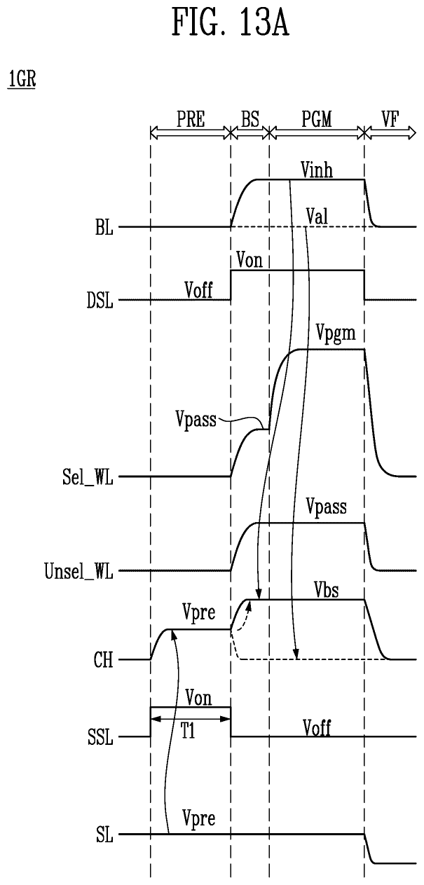

In order to determine the time required to precharge the channel layer, the control circuit 130 may compare the position of the selected page (or selected word line) with the reference position before precharging the channel layer. Information about the reference position may be prestored in the control circuit 130 in the stage of manufacturing the memory device, and may be changed even after the stage of manufacturing the memory device. The reference position may be set depending on an area of memory cells that is affected by disturbance and an area of memory cells that is not affected by disturbance in the memory block, or may be set depending on an area in which the width of a plug is greater than a reference width and an area in which the width of the plug is smaller than the reference width. Examples of the reference position are shown in FIGS. 9A, 9B, and 12, and examples of the plug widths are shown in FIG. 6.

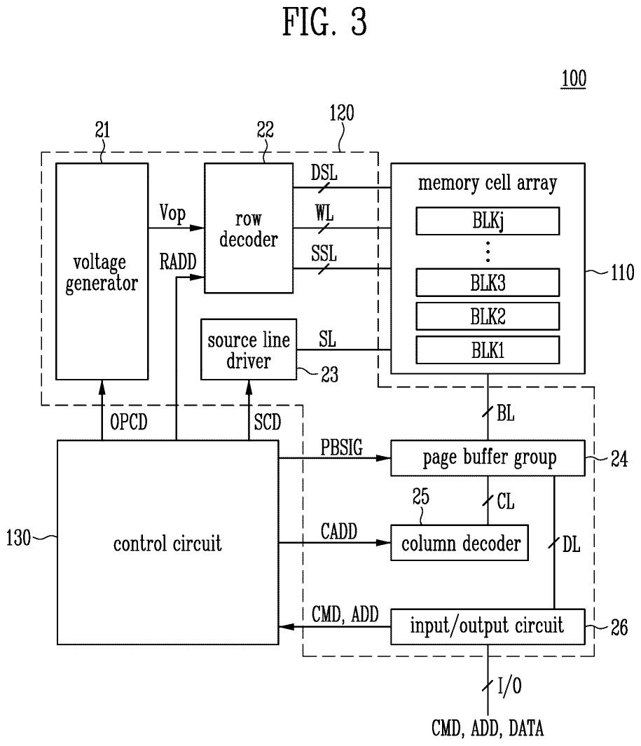

FIG. 3 is a diagram illustrating in detail the memory device 100 according to an embodiment of the present disclosure.

Referring to FIG. 3, the memory device 100 may include the memory cell array 110, the peripheral circuit 120, and the control circuit 130. The memory cell array 110 may include first to j-th memory blocks BLK1 to BLKjm where ‘j’ is a positive integer. Each of the first to j-th memory blocks BLK1 to BLKj may include memory cells capable of storing data. Drain selection lines DSL, word lines WL, source selection lines SSL, a source line SL, and bit lines BL may be connected to each of the first to j-th memory blocks BLK1 to BLKj. The drain selection lines DSL, the word lines WL, and the source selection lines SSL may be connected to each of the first to j-th memory blocks BLK1 to BLKj, and the source line SL and the bit lines BL may be connected in common to the first to j-th memory blocks BLK1 to BLKj.

Each of the first to j-th memory blocks BLK1 to BLKj may be formed in a three-dimensional (3D) structure. Each memory block having a 3D structure may include a plurality of word lines, each coupled to a plurality of memory cells stacked in a direction vertical to a substrate. According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 120 may perform a program operation of storing data in the memory cell array 110, a read operation of outputting data stored in the memory cell array 110, and an erase operation of erasing data stored in the memory cell array 110 under the control of the control circuit 130. For example, the peripheral circuit 120 may include a voltage generator 21, a row decoder 22, a source line driver 23, a page buffer group 24, a column decoder 25, and an input and output (input/output) circuit 26.

The voltage generator 21 may generate various operating voltages Vop that are used for a program operation, a read operation, or an erase operation in response to an operation code OPCD. For example, the voltage generator 21 may generate a program voltage, a turn-on voltage, a turn-off voltage, a verify voltage, a read voltage, a pass voltage, or an erase voltage in response to the operation code OPCD. The operating voltages Vop generated by the voltage generator 21 may have various levels, respectively. The operating voltages Vop may be applied to the drain selection lines DSL, the word lines WL, and the source selection lines SSL of a memory block selected through the row decoder 22. The operating voltages Vop may include the program voltage, the turn-on voltage, the turn-off voltage, the verify voltage, the read voltage, and the pass voltage.

The program voltage may be a voltage that is applied to a word line selected from among the word lines WL during a program operation, and may be used to increase the threshold voltages of memory cells connected to the selected word line. The turn-on voltage may be applied to the drain selection lines DSL or the source selection lines SSL, and may be used to turn on drain select transistors or source select transistors. The turn-off voltage may be applied to the drain selection lines DSL or the source selection lines SSL, and may be used to turn off the drain select transistors or the source select transistors. The verify voltage may be used in a verify operation of determining whether the threshold voltages of selected memory cells have increased to a target level. The verify voltage may be set to various levels according to the target level, and may be applied to the selected word line. The read voltage may be applied to the selected word line during a read operation performed on the selected memory cells. For example, the read voltage may be set to various levels according to the program scheme for the selected memory cells. The pass voltage may be a voltage that is applied to unselected word lines among the word lines WL during a program or read operation, and may be used to turn on memory cells connected to the unselected word lines.

The row decoder 22 may transmit the operating voltages Vop to the drain selection lines DSL, the word lines WL, and the source selection lines SSL, which are connected to the memory block selected according to a row address RADD. For example, the row decoder 22 may be connected to the voltage generator 21 through global lines, and may be connected to the first to j-th memory blocks BLK1 to BLKj through local lines including the drain selection lines DSL, the word lines WL, and the source selection lines SSL.

The source line driver 23 may generate and output a precharge voltage or a ground voltage to be applied to the source line SL in response to a source code SCD. The precharge voltage may be supplied to a channel (e.g., a channel of a string ST) through the source line SL. For example, when the first to j-th memory blocks BLK1 to BLKj included in the memory cell array 110 are included in one plane, the source line SL may be connected in common to the first to j-th memory blocks BLK1 to BLKj included in the plane. When the first to j-th memory blocks BLK1 to BLKj are included in two or more planes, the source line SL may be connected to each of the planes. Here, the source line driver 23 may apply the precharge voltage or the ground voltage to the source line SL connected to the selected plane, and may apply the ground voltage to the source line SL connected to unselected planes or allow the source line SL to float.

The page buffer group 24 may include page buffers connected to the first to j-th memory blocks BLK1 to BLKj through the bit lines BL. During the program operation, the page buffer group 24 may selectively apply a program-enable voltage and a program-inhibit voltage to the bit lines BL in response to page buffer control signals PBSIG. For example, the page buffer group 24 may apply the program-enable voltage to selected bit lines, and may apply the program-inhibit voltage to unselected bit lines. During a verify operation, the page buffer group 24 may sense the currents or voltages of the bit lines BL to store data of the memory cells.

The column decoder 25 may be configured to transfer data between the page buffer group 24 and the input/output circuit 26 in response to a column address CADD. For example, the column decoder 25 may be connected to the page buffer group 24 through column lines CL, and may transmit an enable signal to each of page buffers through the column lines CL. The page buffers included in the page buffer group 24 may receive or output data through data lines DL in response to the enable signal.

The input/output circuit 26 may receive or output a command CMD, an address ADD, or data through input/output lines I/O. For example, the input/output circuit 26 may transmit, to the control circuit 130, the command CMD and the address ADD, received from the controller (e.g., 200 of FIG. 1) through the input/output lines I/O. The input/output circuit 26 may transmit, to the page buffer group 24, the data DATA, received from the controller (e.g., 200 of FIG. 1) through the input/output lines I/O. Alternatively, the input/output circuit 26 may output data, received from the page buffer group 24, to the controller (e.g., 200 of FIG. 1) through the input/output lines I/O.

The control circuit 130 may output the operation code OPCD, the row address RADD, the source code SCD, the page buffer control signals PBSIG, and the column address CADD in response to the command CMD and the address ADD. For example, when the command CMD input to the control circuit 130 is a command corresponding to a program operation, the control circuit 130 may control the devices included in the peripheral circuit 120 so that the program operation is performed on a memory block selected by the address ADD. When the command CMD input to the control circuit 130 is a command corresponding to a read operation, the control circuit 130 may control the devices included in the peripheral circuit 120 so that the read operation is performed on a memory block selected by the address and read data is output. When the command CMD input to the control circuit 130 is a command corresponding to an erase operation, the control circuit 130 may control the peripheral circuit 120 so that the erase operation is performed on a selected memory block.

During the program operation, the control circuit 130 may control the peripheral circuit 120 so that one or more channels of the selected memory block are precharged before the pass voltage is applied to the unselected word lines. The reason for precharging the channels is that, when channel boosting does not normally occur in the channels of the unselected strings, a disturbance may occur in which the threshold voltages of unselected memory cells are changed, thus needing to prevent channel boosting of the unselected strings from being deteriorated.

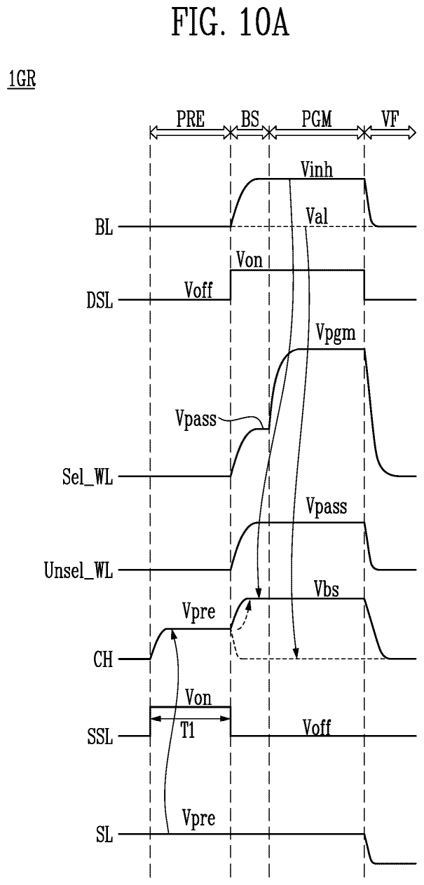

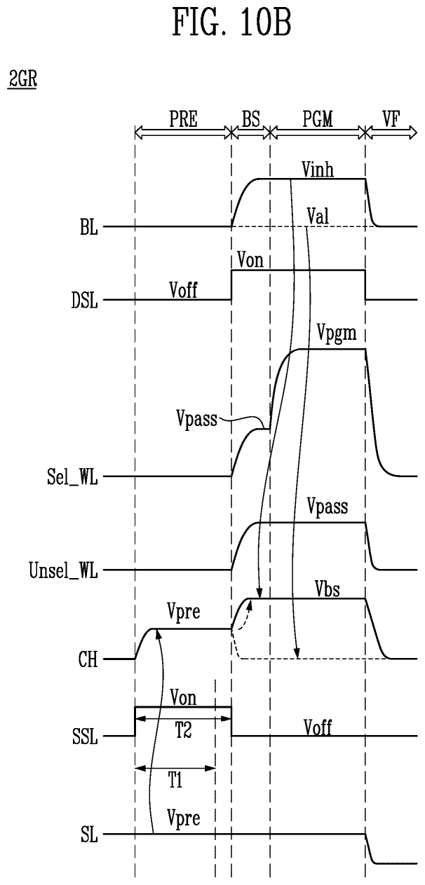

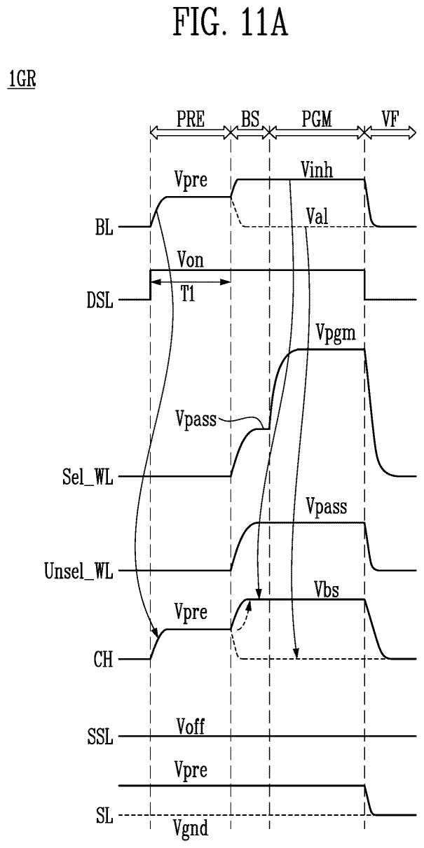

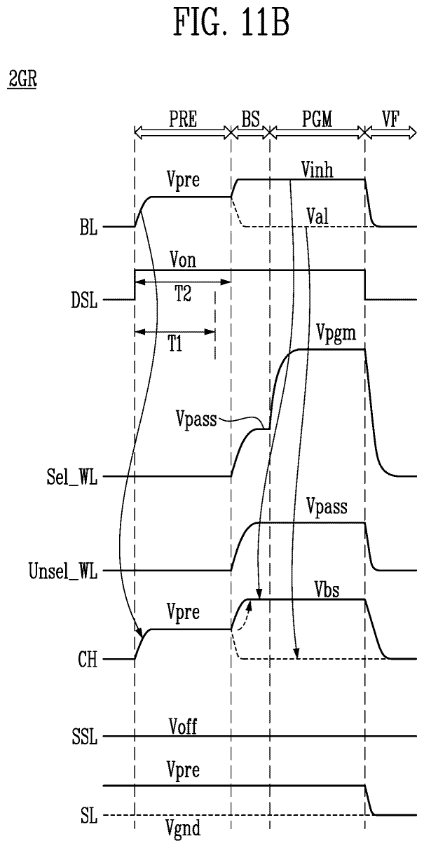

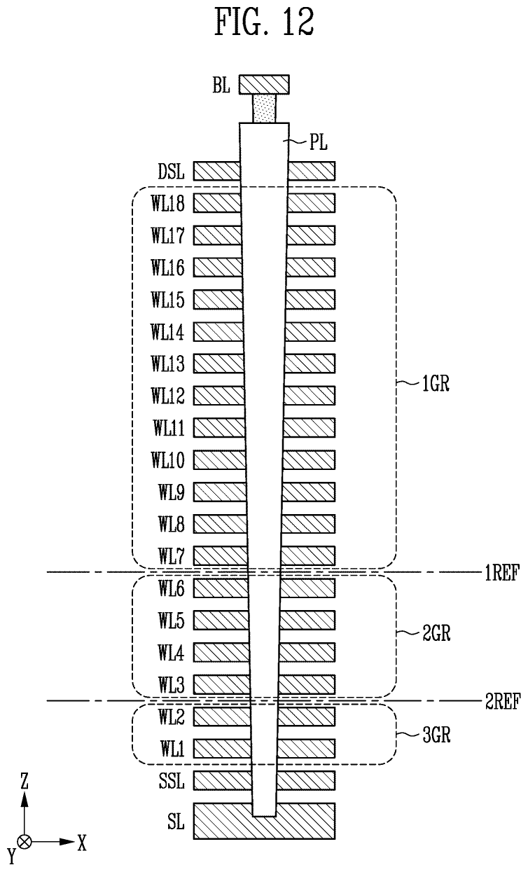

Because a disturbance is more likely to occur as the size of memory cells is smaller, the control circuit 130 according to the present embodiment may adjust the time required to precharge channels depending on the position of the selected word line. For example, when the selected word line is located above a reference position, the size of the memory cells may be larger and the control circuit 130 may control the peripheral circuit 120 to shorten the channel precharge time. When the selected word line is located below the reference position, the size of the memory cells may be smaller and the control circuit 130 may control the peripheral circuit 120 to lengthen the channel precharge time. The channels may be precharged using a method of supplying the precharge voltage to the a channel through the source line SL (e.g., Vpre in FIGS. 10A and 10B), or a method of supplying the precharge voltage to the channels through a bit line BL (e.g., see, Vpre in FIGS. 11A and 11B).

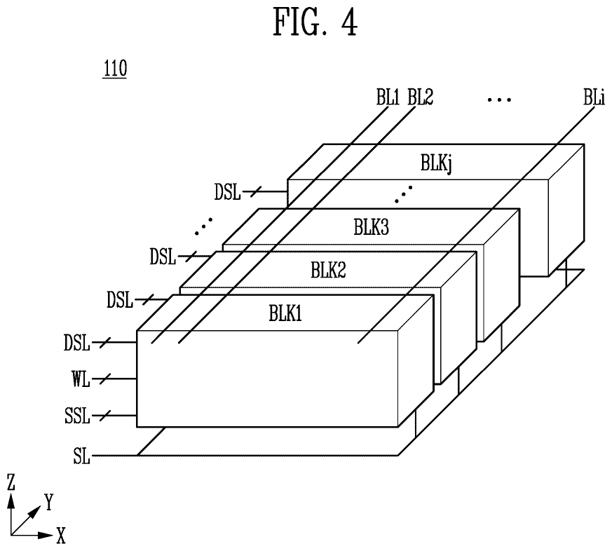

FIG. 4 is a diagram illustrating the memory cell array 110 according to an embodiment of the present disclosure.

Referring to FIG. 4, the memory cell array 110 may include first to j-th memory blocks BLK1 to BLKj. The first to j-th memory blocks BLK1 to BLKj may be arranged to be spaced apart from each other along a Y direction, and may be located between a source line SL and first to i-th bit lines BL1 to BLi, where ‘i’ is a positive integer. Drain selection lines DSL, word lines WL, and source selection lines SSL may be connected to each of the first to j-th memory blocks BLK1 to BLKj. Operating voltages (e.g., Vop of FIG. 3) may be applied through the drain selection lines DSL, the word lines WL, and the source selection lines SSL, which are connected to a selected memory block among the first to j-th memory blocks BLK1 to BLKj. Drain selection lines DSL, the word lines WL, and source selection lines SSL, which are connected to the remaining memory blocks, that is, unselected memory blocks, may float.

In a channel precharge phase according to the present embodiment, one or more channels of the selected memory block may be precharged by the voltage supplied through the source line SL or one or more of the first to i-th bit lines BL1 to BLi. When the precharge voltage is supplied to the one or more channels of the selected memory block through the source line SL, the time required to precharge the channels may be adjusted by adjusting the time during which a turn-on voltage is applied to the source selection lines SSL. By adjusting the time during which the turn-on voltage is applied to the drain selection lines DSL, the time required to precharge the one or more channels may be adjusted.

FIG. 5 is a circuit diagram illustrating a memory block BLKj according to an embodiment of the present disclosure. The memory block BLKj may be a j-th memory block which is representative of the structure of any of the memory blocks BL1, BL2, . . . , BLi shown in FIG. 4.

Referring to FIG. 5, the j-th memory block BLKj may include strings ST connected between a source line SL and first to i-th bit lines BL1 to BLi. The strings ST may be connected in common to the source line SL, may be connected in common to each of the first to i-th bit lines BL1 to BLi, and may be connected to different first to i-th bit lines BL1 to BLi, respectively. The strings ST may be arranged to be spaced apart from each other along an X direction and a Y direction, and may extend along a Z direction. The first to i-th bit lines BL1 to BLi may be arranged to be spaced apart from each other along the X direction, and each of the first to i-th bit lines BL1 to BLi may extend along the Y direction. The numbers of source select transistors SST, first to n-th memory cells M1 to Mn, and drain select transistors DST which are included in each of the cell strings ST may vary depending on the memory device. For example, although, in FIG. 3, one source select transistor SST and one drain select transistor DST are illustrated as being included in each of the strings ST, a plurality of source select transistors SST and a plurality of drain select transistors DST may be included in each string ST.

Gates of source select transistors SST included in different strings ST may be connected to source selection lines SSL, gates of the first to n-th memory cells M1 to Mn may be connected to first to n-th word lines WL1 to WLn, and gates of drain select transistors DST may be connected to drain selection lines DSL1 to DSL5, where ‘n’ is a positive integer. The number of first to fifth drain selection lines DSL1 to DSL5 is not limited to that illustrated in the drawing.

Although the source selection lines SSL may be connected in common to the source select transistors SST arranged along the X and Y directions, some source selection lines SSL arranged along the Y direction may be spaced apart from each other. The first to n-th word lines WL1 to WLn may be connected in common to the memory cells arranged along the X and Y directions. For example, the n-th memory cells Mn arranged along the X and Y directions may be connected in common to the n-th word lines WLn, and the n-th word lines WLn may be connected to each other. For example, (n−1)-th memory cells M (n−1) arranged along the X and Y directions may be connected in common to (n−1)-th word lines WL (n−1), and the (n−1)-th word lines WL (n−1) may be connected to each other. The n-th word lines WLn and the (n−1)-th word lines WL (n−1) may be spaced apart from each other.

A group of memory cells connected in common to any one of the first to n-th word lines WL1 to WLn may be a page (PG). For example, fourth memory cells M4 connected in common to the fourth word line WL4 may form one page (PG). A program operation may be performed on a page (PG) basis. When the fourth word line WL4 is a selected word line, the remaining word lines may be unselected word lines.

The first to fifth drain selection lines DSL1 to DSL5 may be spaced apart from each other in the Y direction. Each of the first to fifth drain selection lines DSL1 to DSL5 may be connected in common to drain select transistors DST arranged in the X direction. Therefore, during a program or read operation, memory cells included in the strings ST connected to a drain selection line selected from among the first to fifth drain selection lines DSL1 to DSL5 may be selected.

When the source select transistors SST are turned on, a voltage supplied to the source line SL may be applied to the channels of the strings ST, whereas when the source select transistors SST are turned off, the source line SL may be electrically disconnected from the strings ST. When a turn-on voltage is applied to the source selection line SSL, the source select transistors SST may be turned on, whereas when a turn-off voltage is applied thereto, the source select transistors SST may be turned off. The turn-on voltage may be a positive voltage higher than 0 V, and the turn-off voltage may be a ground voltage or a negative voltage lower than 0 V. Therefore, when the channels are precharged based on a precharge voltage supplied through the source line SL, a precharge time may be changed depending on the time during which the turn-on voltage is applied to the source selection line SSL.

When the drain select transistors DST are turned on, the voltage supplied to the first to i-th bit lines BL1 to BLi may be applied to the channels of the strings ST, whereas when the drain select transistors DST are turned off, the first to i-th bit lines BL1 to BLi may be electrically disconnected from the strings ST. Below, the drain select transistors DST connected to the first drain selection line DSL1 are described by way of example. When the turn-on voltage is applied to the first drain selection line DSL1, the drain select transistors DST may be turned on, whereas when the turn-off voltage is applied thereto, the drain select transistors DST may be turned off. The turn-on voltage applied to the first drain selection line DSL1 may be a positive voltage higher than 0 V, and the turn-off voltage may be the ground voltage or a negative voltage lower than 0 V. Therefore, when channels are precharged through the first to i-th bit lines BL1 to BLi, the precharge time may be changed depending on the time during which the turn-on voltage is applied to the first drain selection line DSL1.

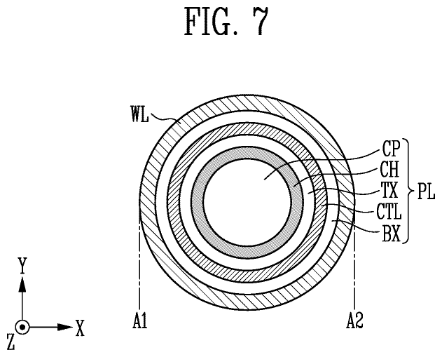

FIG. 6 is a sectional view illustrating the structure of the string ST in FIG. 5, and FIG. 7 is a plan view illustrating the structure of the string ST according to embodiments.

Referring to FIGS. 6 and 7, the string ST may include a plug PL penetrating a source selection line SSL, first to n-th word lines WL1 to WLn, and a drain selection line DSL which are stacked to be spaced apart from each other in the Z direction. The source selection line SSL, the first to n-th word lines WL1 to WLn, and the drain selection line DSL may be formed of a metal material such as tungsten (W), molybdenum (Mo), cobalt (Co), or nickel (Ni), or a semiconductor material such as silicon (Si) or polysilicon (Poly-Si), but the material is not limited thereto. The plug PL may extend along a Z direction between a source line SL and an i-th bit line BLi. A bit line contact Cb may be disposed between the plug PL and the i-th bit line BLi.

The plug PL may include a core pillar CP, a channel layer CH, a tunnel isolation layer TX, a charge trap layer CTL, and a blocking layer BX. The core pillar CP may have the shape of a cylinder, a rectangular pillar, or a polygonal pillar, and may be formed of an insulating material or a conductive material. The channel layer CH may enclose the core pillar CP, and may be formed of polysilicon. The tunnel isolation layer TX may enclose the channel layer CH, and may be formed of an oxide layer. The charge trap layer CTL may enclose the tunnel isolation layer TX, and may be formed of a nitride layer. The blocking layer BX may enclose the charge trap layer CTL, and may be formed of an oxide layer. The bottom of the channel layer CH may contact the source line SL, and the top of the channel layer CH may contact the bit line contact Cb. The bit line contact Cb may be disposed between the i-th bit line BLi and the plug PL.

The plug PL extending in the Z direction may have different widths depending on the height of the plug in the Z direction. Having the plug PL with different widths may be caused by characteristics of a manufacturing process. For example, the width of an upper portion of the plug PL may be greater than that of a lower portion thereof. That is, the width of the plug PL may become smaller in a direction from the top to the bottom. For example, a portion of the plug PL contacting the n-th word line WLn in an uppermost portion of the string ST may have a first width W1, and a portion of the plug PL located in a lowermost portion of the string ST contacting the first word line WL1 may have a second width W2 smaller than the first width W1.

FIG. 7 illustrates the planar structure of the plug PL taken along line A1-A2 in FIG. 6.

Referring to FIG. 7, the plug PL may include the core pillar CP, the channel layer CH, the tunnel isolation layer TX, the charge trap layer CTL, and the blocking layer BX. The channel layer CH may enclose the core pillar CP. The tunnel isolation layer TX may enclose the channel layer CH. The charge trap layer CTL may enclose the tunnel isolation layer TX. The blocking layer BX may encode the charge trap layer CTL. The word line WL may enclose the blocking layer BX.

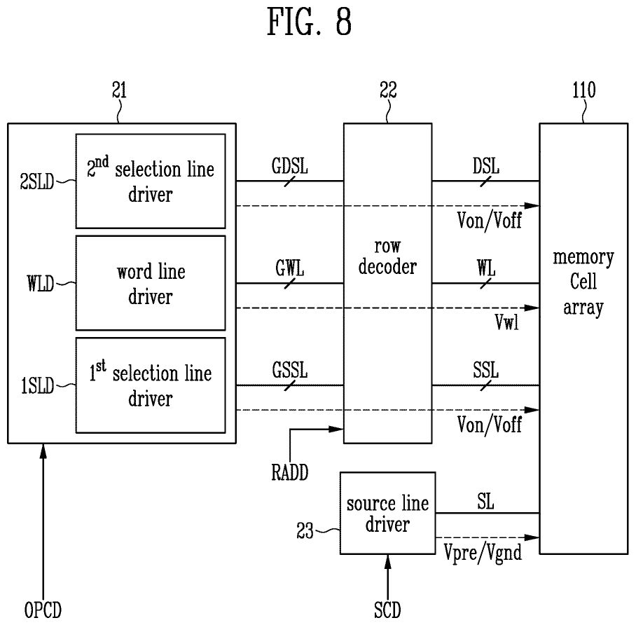

FIG. 8 is a diagram illustrating a path through which operating voltages are transmitted according to an embodiment of the present disclosure.

Referring to FIG. 8, a voltage generator 21 may include a first selection line driver (1st selection line driver; 1SLD), a word line driver (WLD), and a second selection line driver (2nd selection line driver; 2SLD). The first selection line driver 1SLD may generate voltages to be

applied to the source selection lines SSL, and may output the generated voltages through global source selection lines GSSL. For example, the first selection line driver 1SLD may selectively generate a turn-on voltage Von and a turn-off voltage Voff in response to an operation code OPCD. The turn-on or turn-off voltage may be applied to control, for example, a corresponding source select transistor SST (e.g., see FIG. 6). When a turn-on voltage Von is applied to the source select transistor SST (in a precharge phase), a precharge voltage from source line SL may be applied to the channel of the string ST. A turn-off voltage Voff may be applied to the source select transistor SST in a boosting phase, described in greater detail below with reference to FIGS. 10A and 10B.

The word line driver WLD may generate word line voltages Vwl to be applied to word lines WL, respectively, and may output the word line voltages Vwl through global word lines GWL. For example, the word line driver WLD may generate the word line voltages Vwl to be applied to the selected word line in response to the operation code OPCD. The word line voltages Vwl may include a program voltage and a pass voltage.

The second selection line driver 2SLD may generate voltages to be applied to the drain selection lines DSL, and may output the generated voltages through global drain selection lines GDSL. For example, the second selection line driver 2SLD may selectively generate a turn-on voltage Von and a turn-off voltage Voff in response to an operation code OPCD. When a turn-on voltage Von is applied to the drain select transistor DST (e.g., during a boosting phase), a precharge voltage from a corresponding bit line SL may be applied to the channel of the string ST. A turn-off voltage Voff may be applied to the drain select transistor DST during the precharge phase.

The row decoder 22 may select one memory block from among memory blocks included in the memory cell array 110 in response to a row address RADD, may connect the drain selection lines DSL connected to the selected memory block to the global drain selection lines GDSL, may connect the word lines WL connected to the selected memory block to the global word lines GWL, and may connect the source selection lines SSL connected to the selected memory block to the global source selection lines GSSL. Therefore, the turn-on voltage Von or the turn-off voltage Voff applied to the global drain selection lines GDSL may be applied to the drain selection lines DSL, and the word line voltages Vwl applied to the global word lines GWL may be applied to the word lines WL, and the turn-on voltage Von or the turn-off voltage Voff applied to the global source selection lines GSSL may be applied to the source selection lines SSL.

The source line driver 23 may generate the precharge voltage Vpre higher than 0 V, or the ground voltage Vgnd in response to a source code SCD, and may apply the precharge voltage Vpre or the ground voltage Vgnd to the source line SL for precharging the channel of the string ST.

FIGS. 9A and 9B are diagrams illustrating various word line groups according to an embodiment of the present disclosure.

Referring to FIG. 9A, an example structure is shown where first to eighteenth word lines WL1 to WL18 of a string are connected to a memory block. The first to eighteenth word lines WL1 to WL18 may be divided into a first group 1GR and a second group 2GR based on a reference position REF. That is, the first and second groups 1GR and 2GR may be distinguished from each other depending on the reference position REF. When the reference position REF is defined as a position between the sixth and seventh word lines WL6 and WL7, the seventh to eighteenth word lines WL7 to WL18 located above the reference position REF may be included in the first group 1GR, and the first to sixth word lines WL1 to WL6 located below the reference position REF may be included in the second group 2GR. The reference position REF may be set differently depending on the memory device. For example, the reference position REF may be set in an area in which the width of the plug PL is small. For example, the reference position REF may be set depending on the likelihood of a disturbance occurring in memory cells coupled to the plug PL. Smaller memory cells (e.g., located in the first group 1GR) may be more susceptible to disturbances than larger memory cells (e.g., located in the second group 2GR. A disturbance may occur, for example, when the threshold voltages of unselected memory cells are changed during a program operation performed on one or more selected memory cells. For example, this may occur, when the one or more selected memory cells and the unselected memory cells both have a relatively small size, e.g., are coupled to word lines located below a reference position.

In one embodiment, a position between an area in which a disturbance that can affect the reliability of a program operation may occur and an area in which disturbance does not affect reliability occurs, even if the disturbance occurs, may be set as the reference position REF. As the size of the memory cells is smaller (e.g., at positions below the reference position), a disturbance is more likely to occur. Thus, the reference position REF may be set in an area lower than the middle height of the plug PL in this example.

Referring to FIG. 9B, the reference position REF may be set as a position between the first and second word lines WL1 and WL2. Therefore, the first group 1GR may include second to eighteenth word lines WL2 to WL18, and the second group 2GR may include the first word line WL1.

FIGS. 10A and 10B are diagrams illustrating a program method according to a first embodiment of the present disclosure.

FIG. 10A is a diagram for explaining a program method when a selected word line Sel_WL is included in a first group (e.g., 1GR of FIG. 9A or 9B) during a program operation. FIG. 10B is a diagram for explaining a program method when a selected word line Sel_WL is included in a second group (e.g., 2GR of FIG. 9A or 9B) during a program operation.

Referring to FIG. 10A, the program operation may include a precharge phase PRE, a boosting phase BS, a program phase PGM, and a verify phase VF. In the precharge phase PRE, an operation of increasing the potential of the channel layer CH is performed. In the boosting phase BS, an operation of further increasing the potential of the channel layer CH using a pass voltage Vpass is performed. In the program phase PGM, an operation of increasing the threshold voltage of a selected memory cell is performed. In the verify phase VF, an operation of determining whether the threshold voltage of a memory cell has increased to a target voltage is performed. Because the characteristics of the present embodiment are related to the precharge phase PRE, the boosting phase BS, and the program phase PGM, description of the verify phase VF after the program phase PGM will be omitted.

When the precharge phase PRE starts, a turn-off voltage Voff may be applied to the drain selection line DSL to electrically separate the bit line from the string ST. In this case, the selected word line Sel_WL and the remaining unselected word lines Unsel_WL of the string ST may float. Precharging of the channel connected to the selected word line SEL_WL is then performed based on a precharge voltage Vpre. When the precharge voltage Vpre is applied to the source line SL and a turn-on voltage Von is applied to the source selection line SSL, a source select transistor is turned on, thus electrically connecting the source line SL to the channel layer CH. Therefore, the precharge voltage Vpre applied to the source line SL may be supplied to the channel layer CH. As a result, the potential of the channel layer CH may rise to the level of the precharge voltage Vpre (see the voltage corresponding to channel CH).

The precharge phase PRE may be performed during a first time T1 in which the turn-on voltage Von is applied to the source selection line SSL. For example, the first time T1 may be a period from a time point at which the source select transistor is turned on to a time point at which the source select transistor is turned off. When the precharge phase PRE is terminated, the boosting phase BS may be performed.

When the boosting phase BS starts, the turn-off voltage Voff may be applied to the source selection line SSL, a program-inhibit voltage Vinh or a program-enable voltage Val may be applied to the bit line BL, the turn-on voltage Von may be applied to the drain selection line DSL, and the pass voltage Vpass may be applied to the selected word line Sel_WL and the unselected word lines Unsel_WL. The turn-off voltage Voff may be set to a ground voltage or 0 V. The program-inhibit voltage Vinh is a positive voltage higher than 0 V, and may be used to prevent the threshold voltages of unselected memory cells from being increased due to the program voltage. The program-enable voltage Val may be set to the ground voltage or 0 V.

Because the turn-on voltage Von is applied to the drain selection line DSL, the drain select transistor may be turned on. When the drain select transistor is turned on, the channel layer CH is electrically connected to the bit line BL. As a result, the voltage of the channel layer CH is further increased. When the program-enable voltage Val is applied to the bit line BL, the voltage of the channel layer CH may be decreased due to the program-enable voltage Val (e.g., see the dotted line in FIG. 10A). When the program-inhibit voltage Vinh is applied to the bit line BL, the voltage of the channel layer CH may be boosted by the pass voltage Vpass applied to the selected word line Sel_WL and the unselected word lines Unsel_WL, without being decreased due to the program-inhibit voltage Vinh. Therefore, when the program-inhibit voltage Vinh is applied to the bit line BL, the potential of the channel layer CH may be increased to a boosting voltage Vbs higher than the precharge voltage Vpre. When the boosting phase BS is terminated, the program phase PGM may start.

When the program phase PGM starts, a program voltage Vpgm higher than the pass voltage Vpass may be applied to the selected word line Sel_WL. A memory cell connected to a channel layer CH having a potential lower than the precharge voltage Vpre is programmed due to a voltage difference between the channel layer CH and the selected word line Sel_WL. The memory cell connected to the channel layer CH having the boosting voltage Vbs is not programmed due to the boosting voltage Vbs.

When the program phase PGM is terminated, the bit line BL, the drain selection line DSL, the selected word line Sel_WL, the unselected word lines Unsel_WL, the channel layer CH, the source selection line SL, and the source line SL may be discharged. Subsequently, the verify phase VF may be performed.

The program operation performed in the case where the selected word line Sel_WL is included in the first group 1GR (above the reference position REF and corresponding to memory cells that are larger in size) has been described with reference to FIG. 10A. Here, even when a disturbance occurs by a program operation performed on a memory cell coupled to the selected word line Sel_WL, memory cells coupled to unselected word lines in the first group 1GR are not adversely affected. The program operation performed in the case where the selected word line Sel_WL is included in the second group 2GR will be described below with reference to FIG. 10B.

Referring to FIG. 10B, the boosting phase BS, the program phase PGM, and the verify phase VF, except the time during which the precharge phase PRE is performed, are performed in the same manner as the boosting phase BS, the program page PGM, and the verify phase VF, which are described above with reference to FIG. 10A, and thus repeated description thereof will be omitted.

When the selected word line Sel_WL is included in the second group 2GR having memory cells coupled to unselected word lines Unsel_WL that are vulnerable to disturbance, the time during which the precharge phase PRE is performed may be set to a second time T2 longer than the first time T1 so as to reduce influence of a disturbance, e.g., a disturbance that may occur in memory cells coupled to an unselected word line in the second group 2GR as a result of performing a program operation for a memory cell of a selected word line. Such a disturbance, if not corrected, may change the threshold voltages of the memory cells coupled to the unselected word line(s). By compensating for this disturbance, reliability of the memory device may be improved.

More specifically, because the precharge phase PRE is performed for a longer period of time (compared with the precharge phase PRE performed for word lines above the reference position in the first group 1GR), the precharge voltage Vpre may be sufficiently transferred to the channel layer CH. As a result, boosting of the channel layer CH may effectively occur in the boosting phase BS performed after the charge phase PRE. Therefore, during the program operation on the second group 2GR including memory cells having a relatively small size, disturbance may be prevented from occurring.

As described above, when the selected word line Sel_WL is included in the first group 1GR having memory cells that are not affected by a disturbance, the time required for the program operation (T1) may be shortened by shortening the time required for precharging the channel during the precharge phase PRE. When the selected word line Sel_WL is included in the second group 2GR (and thus has unselected memory cells that are affected by disturbance), the reliability of the program operation may be improved by increasing the time (T2) required during the precharge phase PRE.

FIGS. 11A and 11B are diagrams illustrating a program method according to a second embodiment of the present disclosure. In the first embodiment described above with reference to FIGS. 10A and 10B, the channel layer CH is precharged through the source line SL. In the second embodiment, the channel layer CH may be precharged through the bit line BL in the second embodiment.

FIG. 11A is a diagram for explaining a program method when a selected word line Sel_WL is included in a first group (e.g., 1GR of FIG. 9A or 9B) during a program operation. FIG. 11B is a diagram for explaining a program method when a selected word line Sel_WL is included in a second group (e.g., 2GR of FIG. 9A or 9B) during a program operation.

Referring to FIG. 11A, the program operation may include a precharge phase PRE, a boosting phase BS, a program phase PGM, and a verify phase VF. In the precharge phase PRE, an operation of increasing the potential of the channel layer CH is performed based on a precharge voltage Vpre applied to a corresponding bit line BL. In the boosting phase BS, an operation of further increasing the potential of the channel layer CH using a pass voltage Vpass is performed. In the program phase PGM, an operation of increasing the threshold voltage of a selected memory cell (e.g., a memory cell coupled to a selected word line) is performed. During the verify period VF, an operation of determining whether the threshold voltage of a memory cell has increased to a target voltage is performed. Because the characteristics of the present embodiment are related to the precharge phase PRE, the boosting phase BS, and the program phase PGM, description of the verify phase VF after the program phase PGM will be omitted.

When the precharge phase PRE starts, a turn-off voltage Voff may be applied to the source selection line SSL to turn off a corresponding source select transistor SST. In this case, the selected word line Sel_WL and the unselected word lines Unsel_WL may float. A ground voltage Vgnd or a precharge voltage Vpre may be applied to the source line SL. Unlike FIG. 10A, the precharge voltage Vpre may be applied to the bit line BL. The precharge voltage Vpre applied to the bit line BL may be identical to or different from the precharge voltage Vpre applied to the source line SL in FIG. 10A.

The turn-on voltage Von may be applied to the drain selection line DSL. When the turn-on voltage Von is applied to the drain selection line DSL, the drain select transistor DST is turned on, thus electrically connecting the bit line BL to the channel layer CH. Therefore, the precharge voltage Vpre applied to the bit line BL may be supplied to the channel layer CH. In this case, the potential of the channel layer CH may rise to the level of the precharge voltage Vpre. The precharge phase PRE may be performed during a first time T1 after the precharge voltage Vpre is applied to the bit line BL and the turn-on voltage Von is applied to the drain selection line DSL. For example, the first time T1 may be a period from a time point at which the drain select transistor DST is turned on to a time point at which the program-enable voltage Val or the program-inhibit voltage Vinh starts to be applied to the bit line BL. When the precharge phase PRE is terminated, the boosting phase BS may be performed.

When the boosting phase BS starts, the program-inhibit voltage Vinh or the program-enable voltage Val is applied to the bit line BL, and the pass voltage Vpass may be applied to the selected word line Sel_WL and the unselected word line(s) Unsel_WL. The program-inhibit voltage Vinh is a positive voltage higher than 0 V, and may be used to prevent the threshold voltages of unselected memory cells from being increased due to the program voltage. The program-enable voltage Val may be set, for example, to the ground voltage or 0 V.

Because the turn-on voltage Von continues to be applied to the drain selection line DSL, the drain select transistor DST may remain turned on. When the program-enable voltage Val is applied to the bit line BL, the voltage of the channel layer CH may be decreased due to the program-enable voltage Val. When the program-inhibit voltage Vinh is applied to the bit line BL, the voltage of the channel layer CH may be boosted by the pass voltage Vpass applied to the selected word line Sel_WL and the unselected word lines Unsel_WL, without being decreased due to the program-inhibit voltage Vinh. Therefore, when the program-inhibit voltage Vinh is applied to the bit line BL, the potential of the channel layer CH may be increased to a boosting voltage Vbs higher than the precharge voltage Vpre. When the boosting phase BS is terminated, the program phase PGM may start.

When the program phase PGM starts, a program voltage Vpgm higher than the pass voltage Vpass may be applied to the selected word line Sel_WL. A memory cell connected to the channel layer CH having a potential lower than the precharge voltage Vpre is programmed due to a voltage difference between the channel layer CH and the selected word line Sel_WL. The memory cell connected to the channel layer CH having the boosting voltage Vbs is not programmed due to the boosting voltage Vbs.

When the program phase PGM is terminated, the bit line BL, the drain selection line DSL, the selected word line Sel_WL, the unselected word lines Unsel_WL, the channel layer CH, the source selection line SL, and the source line SL may be discharged. Subsequently, the verify phase VF may be performed.

The program operation performed in the case where the selected word line Sel_WL is included in the first group 1GR has been described with reference to FIG. 11A. The program operation performed in the case where the selected word line Sel_WL is included in the second group 2GR will be described below with reference to FIG. 11B.

Referring to FIG. 11B, the boosting phase BS, the program phase PGM, and the verify phase VF, except the time during which the precharge phase PRE is performed, are performed in the same manner as the boosting phase BS, the program page PGM, and the verify phase VF, which are described above with reference to FIG. 11A, and thus repeated description thereof will be omitted.

When the selected word line Sel_WL is included in the second group 2GR having memory cells of unselected word lines that are vulnerable to disturbance, the time during which the precharge phase PRE is performed may be set to a second time T2 longer than the first time T1, so as to prevent such a disturbance. Because the precharge phase PRE is performed longer than T1, the precharge voltage Vpre may be sufficiently transferred to the channel layer CH, and thus boosting of the channel layer CH may effectively occur in the boosting phase BS performed after the charge phase PRE. Therefore, during the program operation on the second group 2GR including memory cells having a relatively small size, disturbance may be prevented from occurring in the unselected memory cells corresponding to word lines in the second group 2GR.

As described above, when the selected word line Sel_WL is included in the first group 1GR that is not affected by disturbance, the time required for the program operation may be shortened by shortening the time required for the precharge phase PRE. When the selected word line Sel_WL is included in the second group 2GR that is affected by disturbance, the reliability of the program operation may be improved by increasing the time required for the precharge phase PRE.

FIG. 12 is a diagram illustrating word line groups according to an embodiment of the present disclosure.

Referring to FIG. 12, in this embodiment, a plurality of reference positions 1REF and 2REF may be set. For example, first and second reference positions 1REF and 2REF may be set in one memory block. The first and second reference positions 1REF and 2REF may be set at different heights relative to the channel, and thus may partition the word lines into three groups. This embodiment has been described with two reference positions, but more than two reference positions may be set in other embodiments.

More specifically, when a structure in which first to eighteenth word lines WL1 to WL18 are connected to a memory block is described by way of example, the first to eighteenth word lines WL1 to WL18 may be divided into first to third groups 1GR to 3GR. The first to third groups 1GR to 3GR may be divided depending on the first and second reference positions 1REF and 2REF. When the first reference position 1REF is defined as a position between sixth and seventh word lines WL6 and WL7 and the second reference position 2REF is defined as a position between the second and third word lines WL2 and WL3, seventh to eighteenth word lines WL7 to WL18 located above the first reference position 1REF may be included in the first group 1GR, the third to sixth word lines WL3 to WL6 (disposed between the first reference position 1REF and the second reference position 2REF) may be included in the second group 2GR, and the first and second word lines WL1 and WL2 located below the second reference position 2REF may be included in the third group 3GR.

The first and second reference positions 1REF and 2REF may be set differently depending on the memory device. For example, the first and second reference positions 1REF and 2REF may be set in an area in which the width of the plug PL is small. For example, the first and second reference positions 1REF and 2REF may be set depending on the disturbance of memory cells included in the plug PL. For example, a position between an area in which disturbance that can affect the reliability of a program operation may occur and an area in which disturbance does not affect the reliability occurs, even if the disturbance occurs, may be set as the first reference position 1REF. In addition, the second reference position 2REF may be set to identify a region in which the impact of disturbance is greater in the area in which disturbance that can affect the reliability of the program operation may occur.

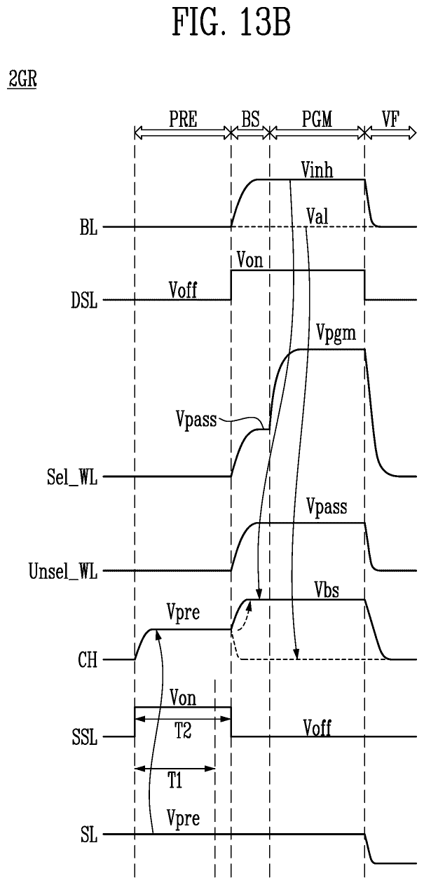

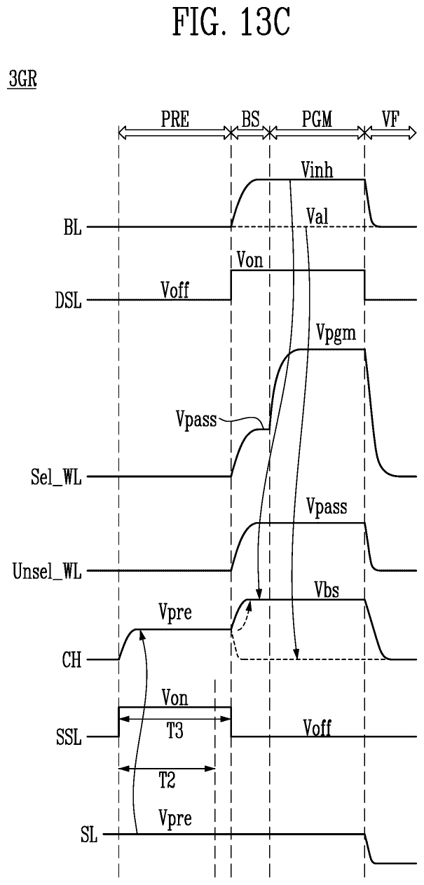

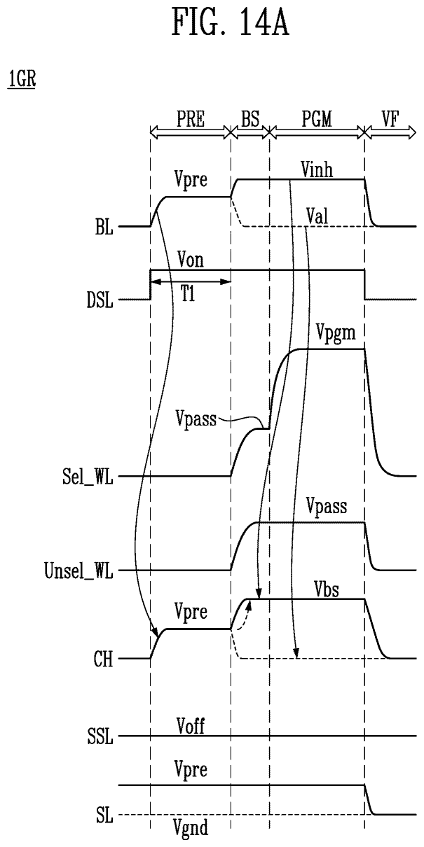

FIGS. 13A to 13C are diagrams illustrating a program method according to a third embodiment of the present disclosure. FIG. 13A is a diagram for explaining a program method when a selected word line Sel_WL is included in a first group (e.g., 1GR of FIG. 12) during a program operation. FIG. 13B is a diagram for explaining a program method when a selected word line Sel_WL is included in a second group (e.g., 2GR of FIG. 12) during a program operation. FIG. 13C is a diagram for explaining a program method when the selected word line Sel_WL is included in a third group (e.g., 3GR of FIG. 12) during a program operation.

In the examples of FIGS. 13A to 13C, the precharge voltage for the channel is provided from the source line through a corresponding source select transistor SST.

Referring to FIG. 13A, the program operation may include a precharge phase PRE, a boosting phase BS, a program phase PGM, and a verify phase VF. In the precharge phase PRE, an operation of increasing the potential of the channel layer CH is performed. In the boosting phase BS, an operation of further increasing the potential of the channel layer CH using a pass voltage Vpass is performed. In the program phase PGM, an operation of increasing the threshold voltage of a selected memory cell is performed. During the verify period VF, an operation of determining whether the threshold voltage of a memory cell has increased to a target voltage is performed. Because the characteristics of the present embodiment are related to the precharge phase PRE, the boosting phase BS, and the program phase PGM, description of the verify phase VF after the program phase PGM will be omitted.

When the precharge phase PRE starts, a turn-off voltage Voff may be applied to the drain selection line DSL to turn off the drain select transistors DST. As a result, the selected word line Sel_WL and the unselected word lines Unsel_WL may float. When a precharge voltage Vpre is applied to the source line SL and a turn-on voltage Von is applied to the source selection line SSL, the source select transistor SST is turned on, thus electrically connecting the source line SL to the channel layer CH. Therefore, the precharge voltage Vpre applied to the source line SL may be supplied to the channel layer CH. As a result, the potential of the channel layer CH may rise to the level of the precharge voltage Vpre.

The precharge phase PRE may be performed during a first time T1, in which the turn-on voltage Von is applied to the source selection line SSL. For example, the first time T1 may be a period from a time point at which the source select transistor is turned on to a time point at which the source select transistor is turned off. When the precharge phase PRE is terminated, the boosting phase BS may be performed.

When the boosting phase BS starts, the turn-off voltage Voff may be applied to the source selection line SSL, a program-inhibit voltage Vinh or a program-enable voltage Val may be applied to the bit line BL, the turn-on voltage Von may be applied to the drain selection line DSL, and the pass voltage Vpass may be applied to the selected word line Sel_WL and the unselected word lines Unsel_WL. The turn-off voltage Voff may be set to a ground voltage or 0 V. The program-inhibit voltage Vinh is a positive voltage higher than 0 V, and may be used to prevent the threshold voltages of unselected memory cells from being adversely affected (e.g., increased) due to the program voltage applied for the selected word line. The program-enable voltage Val may be set to the ground voltage or 0 V.

Because the turn-on voltage Von is applied to the drain selection line DSL, the drain select transistor DST may be turned on. When the drain select transistor DST is turned on, the channel layer CH is electrically connected to the bit line BL. When the program-enable voltage Val is applied to the bit line BL (see the dotted line in FIG. 13A), the voltage of the channel layer CH may be decreased due to the program-enable voltage Val. When the program-inhibit voltage Vinh is applied to the bit line BL, the voltage of the channel layer CH may be boosted by the pass voltage Vpass applied to the selected word line Sel_WL and the unselected word lines Unsel_WL, without being decreased due to the program-inhibit voltage Vinh. Therefore, when the program-inhibit voltage Vinh is applied to the bit line BL, the potential of the channel layer CH may be increased to a boosting voltage Vbs higher than the precharge voltage Vpre. When the boosting phase BS is terminated, the program phase PGM may start.

When the program phase PGM starts, a program voltage Vpgm higher than the pass voltage Vpass may be applied to the selected word line Sel_WL. A memory cell connected to a channel layer CH having a potential lower than the precharge voltage Vpre is programmed due to a voltage difference between the channel layer CH and the selected word line Sel_WL. The memory cell connected to the channel layer CH having the boosting voltage Vbs is not programmed due to the boosting voltage Vbs.

When the program phase PGM is terminated, the bit line BL, the drain selection line DSL, the selected word line Sel_WL, the unselected word lines Unsel_WL, the channel layer CH, the source selection line SL, and the source line SL may be discharged. Subsequently, the verify phase VF may be performed.

The program operation performed in the case where the selected word line Sel_WL is included in the first group 1GR has been described with reference to FIG. 13A. The program operation performed in the case where the selected word line Sel_WL is included in the second group 2GR will be described below with reference to FIG. 13B.

Referring to FIG. 13B, the boosting phase BS, the program phase PGM, and the verify phase VF, except the time during which the precharge phase PRE is performed, are performed in the same manner as the boosting phase BS, the program page PGM, and the verify phase VF, which are described above with reference to FIG. 13A, and thus repeated description thereof will be omitted.

When the selected word line Sel_WL is included in the second group 2GR vulnerable to disturbance, the time during which the precharge phase PRE is performed may be set to a second time T2 longer than the first time T1, so as to reduce the influence of disturbances on memory cells coupled to unselected word lines in the second group 2GR. Because the precharge phase PRE is performed for a longer period of time T2, the precharge voltage Vpre may be sufficiently transferred to the channel layer CH, and thus boosting of the channel layer CH may effectively occur in the boosting phase BS performed after the charge phase PRE. Therefore, during the program operation on the second group 2GR including memory cells having a relatively small size, disturbance may be prevented from occurring.

Referring to FIG. 13C, the boosting phase BS, the program phase PGM, and the verify phase VF, except the time during which the precharge phase PRE is performed, are performed in the same manner as the boosting phase BS, the program page PGM, and the verify phase VF, which are described above with reference to FIG. 13B, and thus repeated description thereof will be omitted.

When the selected word line Sel_WL is included in the third group 3GR, having memory cells which are more vulnerable to disturbance than the second group 2GR, the time during which the precharge phase PRE is to be performed may be set to a third time T3 longer than the second time T2, so as to reduce the influence of disturbance caused by a program operation on a selected memory cell on memory cells coupled to unselected word lines. Because the precharge phase PRE is performed for a longer period of time T3, the precharge voltage Vpre may be sufficiently transferred to the channel layer CH, and thus boosting of the channel layer CH may effectively occur in the boosting phase BS performed after the charge phase PRE. Therefore, during the program operation on the third group 3GR including memory cells having a relatively small size, disturbance may be prevented from occurring on unselected memory cells.

As described above, when the selected word line Sel_WL is included in the first group 1GR having memory cells that are not affected by disturbance, the time required for the program operation may be shortened by shortening the time required for the precharge phase PRE. When the selected word line Sel_WL is included in the second and third groups 2GR and 3GR having memory cells that are affected by disturbance, the reliability of the program operation may be improved by increasing the time required for the precharge phase PRE.

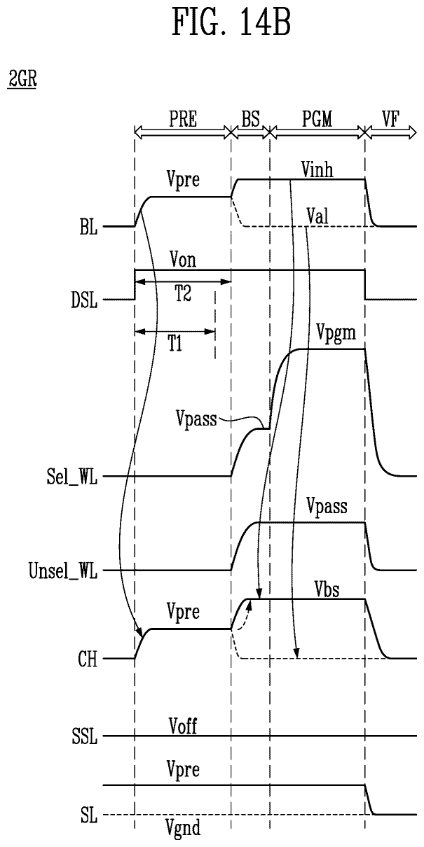

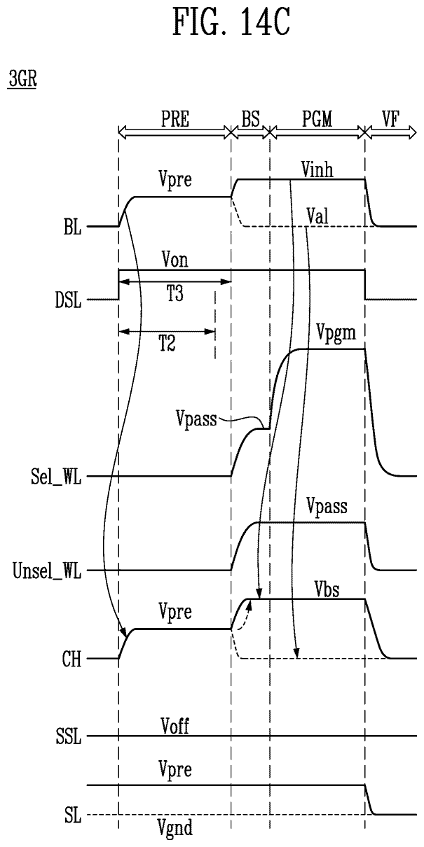

FIGS. 14A to 14C are diagrams illustrating a program method according to a fourth embodiment of the present disclosure. In this embodiment, the precharge voltage is supplied by the bit line BL. Although, in the third embodiment described above with reference to FIGS. 13A to 13C, the channel layer CH is precharged through the source line SL, the channel layer CH may be precharged through the bit line BL in the fourth embodiment to be described with reference to FIGS. 14A to 14C.

FIG. 14A is a diagram for explaining a program method when a selected word line Sel_WL is included in a first group (e.g., 1GR of FIG. 12) during a program operation. FIG. 14B is a diagram for explaining a program method when a selected word line Sel_WL is included in a second group (e.g., 2GR of FIG. 12) during a program operation. FIG. 14C is a diagram for explaining a program method when the selected word line Sel_WL is included in a third group (e.g., 3GR of FIG. 12) during a program operation.

Referring to FIG. 14A, the program operation may include a precharge phase PRE, a boosting phase BS, a program phase PGM, and a verify phase VF. In the precharge phase PRE, an operation of increasing the potential of the channel layer CH is performed. In the boosting phase BS, an operation of further increasing the potential of the channel layer CH using a pass voltage Vpass is performed. In the program phase PGM, an operation of increasing the threshold voltage of a selected memory cell is performed. During the verify period VF, an operation of determining whether the threshold voltage of a memory cell has increased to a target voltage is performed. Because the characteristics of the present embodiment are related to the precharge phase PRE, the boosting phase BS, and the program phase PGM, description of the verify phase VF after the program phase PGM will be omitted.

When the precharge phase PRE starts, a turn-off voltage Voff may be applied to the source selection line SSL, and the selected word line Sel_WL and the unselected word lines Unsel_WL may float. A ground voltage Vgnd or a precharge voltage Vpre may be applied to the source line SL. The precharge voltage Vpre may be applied to the bit line BL. The precharge voltage Vpre applied to the bit line BL may be identical to or different from the precharge voltage Vpre applied to the source line SL. The turn-on voltage Von may be applied to the drain selection line DSL. When the turn-on voltage Von is applied to the drain selection line DSL, the drain select transistor DST is turned on, thus electrically connecting the bit line BL to the channel layer CH. Therefore, the precharge voltage Vpre applied to the bit line BL may be supplied to the channel layer CH. As a result, the potential of the channel layer CH may rise to the level of the precharge voltage Vpre.

The precharge phase PRE may be performed during a first time T1 after the precharge voltage Vpre is applied to the bit line BL and the turn-on voltage Von is applied to the drain selection line DSL. For example, the first time T1 may be a period from a time point at which the drain select transistor DST is turned on to a time point at which the program-enable voltage Val or the program-inhibit voltage Vinh starts to be applied to the bit line BL. When the precharge phase PRE is terminated, the boosting phase BS may be performed.

When the boosting phase BS starts, the program-inhibit voltage Vinh or the program-enable voltage Val is applied to the bit line BL, and the pass voltage Vpass may be applied to the selected word line Sel_WL and the unselected word line(s) Unsel_WL. The program-inhibit voltage Vinh is a positive voltage higher than 0 V, and may be used to prevent the threshold voltages of unselected memory cells from being increased due to the program voltage applied to memory cells coupled to the selected word line. The program-enable voltage Val may be set to the ground voltage or 0 V.

Because the turn-on voltage Von continues to be applied to the drain selection line DSL, the drain select transistor DST may remain turned on. When the program-enable voltage Val is applied to the bit line BL (see the dotted line in FIG. 14A), the voltage of the channel layer CH may be decreased due to the program-enable voltage Val. When the program-inhibit voltage Vinh is applied to the bit line BL, the voltage of the channel layer CH may be boosted by the pass voltage Vpass applied to the selected word line Sel_WL and the unselected word lines Unsel_WL, without being decreased due to the program-inhibit voltage Vinh. Therefore, when the program-inhibit voltage Vinh is applied to the bit line BL, the potential of the channel layer CH may be increased to a boosting voltage Vbs higher than the precharge voltage Vpre. When the boosting phase BS is terminated, the program phase PGM may start.

When the program phase PGM starts, a program voltage Vpgm higher than the pass voltage Vpass may be applied to the selected word line Sel_WL. A memory cell connected to a channel layer CH having a potential lower than the precharge voltage Vpre is programmed due to a voltage difference between the channel layer CH and the selected word line Sel_WL. The memory cell connected to the channel layer CH having the boosting voltage Vbs is not programmed due to the boosting voltage Vbs.

When the program phase PGM is terminated, the bit line BL, the drain selection line DSL, the selected word line Sel_WL, the unselected word lines Unsel_WL, the channel layer CH, the source selection line SL, and the source line SL may be discharged. Subsequently, the verify phase VF may be performed.

The program operation performed in the case where the selected word line Sel_WL is included in the first group 1GR has been described with reference to FIG. 14A. The program operation performed in the case where the selected word line Sel_WL is included in the second group 2GR will be described below with reference to FIG. 14B.

Referring to FIG. 14B, the boosting phase BS, the program phase PGM, and the verify phase VF, except the time during which the precharge phase PRE is performed, are performed in the same manner as the boosting phase BS, the program page PGM, and the verify phase VF, which are described above with reference to FIG. 14A, and thus repeated description thereof will be omitted.

When the selected word line Sel_WL is included in the second group 2GR having memory cells that are vulnerable to disturbance, the time during which the precharge phase PRE is performed may be set to a second time T2 longer than the first time T1, so as to prevent disturbance. Because the precharge phase PRE is performed longer, the precharge voltage Vpre may be sufficiently transferred to the channel layer CH, and thus boosting of the channel layer CH may effectively occur in the boosting phase BS performed after the charge phase PRE.

Therefore, during the program operation on the second group 2GR including memory cells having a relatively small size, disturbance may be prevented from occurring in the memory cells.

The program operation performed in the case where the selected word line Sel_WL is included in the second group 2GR will be described below with reference to FIG. 14B. The program operation performed in the case where the selected word line Sel_WL is included in the third group 3GR will be described below with reference to FIG. 14C.

Referring to FIG. 14C, the boosting phase BS, the program phase PGM, and the verify phase VF, except the time during which the precharge phase PRE is performed, are performed in the same manner as the boosting phase BS, the program page PGM, and the verify phase VF, which are described above with reference to FIG. 14B, and thus repeated description thereof will be omitted.

When the selected word line Sel_WL is included in the third group 3GR having memory cells that are vulnerable to disturbance, the time during which the precharge phase PRE is performed may be set to a third time T3 longer than the second time T2, so as to prevent disturbance. As the precharge phase PRE is performed longer, the precharge voltage Vpre may be sufficiently transferred to the channel layer CH, and thus boosting of the channel layer CH may effectively occur in the boosting phase BS performed after the charge phase PRE.

Therefore, during the program operation on the third group 3GR including memory cells having a relatively small size, disturbance may be prevented from occurring in the memory cells. The memory cells that are coupled to word lines of the third group 3GR may be the same size or smaller than the memory cells that are coupled to the word lines in the second group 2GR.

As described above, when the selected word line Sel_WL is included in the first group 1GR that having memory cells (e.g., threshold voltages) that are not affected by disturbance, the time required for the program operation may be shortened by shortening the time required for the precharge phase PRE. When the selected word line Sel_WL is included in the second and third groups 2GR and 3GR having memory cells (e.g., threshold voltages) that are affected by disturbance, the reliability of the program operation may be improved by increasing the time required for the precharge phase PRE.

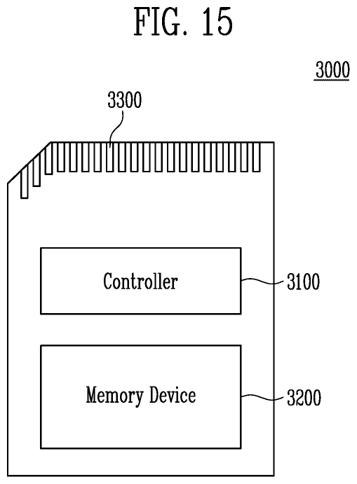

FIG. 15 is a diagram illustrating a memory card system 3000 to which a memory device according to an embodiment of the present disclosure is applied.

Referring to FIG. 15, the memory card system 3000 includes a controller 3100, a memory device 3200, and a connector 3300. The controller 3100 is connected to the memory device 3200. The controller 3100 may access the memory device 3200. For example, the controller 3100 may control a program operation, a read operation, or an erase operation of the memory device 3200 or control background operations of the memory device 3200. The controller 3100 may provide an interface between the memory device 3200 and a host. The controller 3100 may run firmware for controlling the memory device 3200. For example, the controller 3100 may include components, such as a random access memory (RAM), a processor, a host interface, a memory interface, and an error correction circuit.

The controller 3100 may communicate with an external device through the connector 3300. The controller 3100 may communicate with an external device (e.g., a host) based on a specific communication standard. In an embodiment, the controller 3100 may communicate with the external device through at least one of various communication standards such as universal serial bus (USB), multimedia card (MMC), embedded MMC (eMMC), peripheral component interconnection (PCI), PCI-express (PCI-e or PCIe), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 3300 may be defined by at least one of the above-described various communication standards.

The memory device 3200 may include memory cells, and may be configured in the same manner as the memory device 100 illustrated in FIG. 3. For example, in order to shorten the time required for the program operation and prevent disturbance from occurring, the memory device 3200 according to the present embodiment may adjust the time required for channel precharging depending on the size of memory cells included in a selected page during the program operation on the selected page in a selected memory block. For example, a precharge phase performed for memory cells that are smaller in size relative to a reference position of the channel may have a longer precharge period than memory cells that are larger in size relative to the reference position.

The controller 3100 and the memory device 3200 may be integrated into a single semiconductor device to form a memory card. For example, the controller 3100 and the memory device 3200 may be integrated into a single semiconductor device and may then form a memory card such as a PC card (personal computer memory card international association: PCMCIA), a compact flash card (CF), a smart media card (SM or SMC), a memory stick, a multimedia card (MMC, RS-MMC, MMCmicro or eMMC), a secure digital (SD) card (SD, miniSD, microSD, or SDHC), universal flash storage (UFS), or the like.

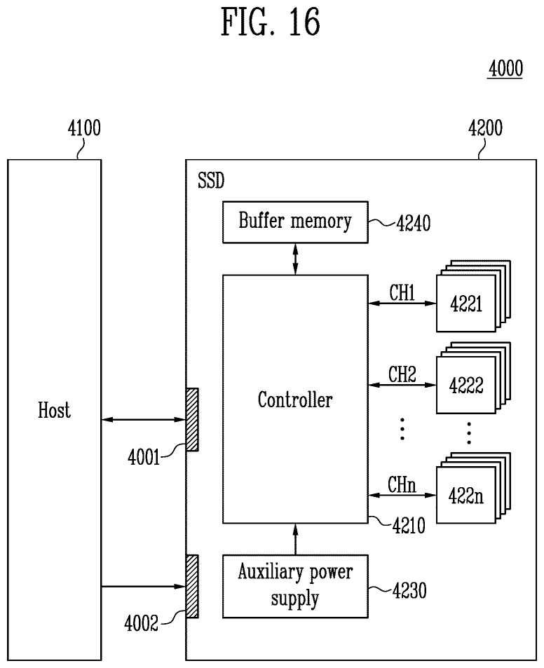

FIG. 16 is a diagram illustrating a solid state drive (SSD) system 4000 to which a memory device according to an embodiment of the present disclosure is applied.

Referring to FIG. 16, the SSD system 4000 may include a host 4100 and an SSD 4200. The SSD 4200 may exchange signals with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. In an embodiment, the signals may be signals based on the interfaces of the host 4100 and the SSD 4200. For example, the signals may be signals defined by at least one of interfaces such as universal serial bus (USB), multimedia card (MMC), embedded MMC (eMMC), peripheral component interconnection (PCI), PCI-express (PCI-e or PCIe), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include cells in which data can be stored. Each of the plurality of memory devices 4221 to 422n may be configured in the same manner as the memory device 100 illustrated in FIG. 3. In order to shorten the time required for performing a program operation and to prevent disturbance, at least one of the plurality of memory devices 4221 to 422n according to the present embodiment may adjust the time required for channel precharging depending on the size of memory cells included in a selected page during a program operation on the selected page in a selected memory block. For example, a precharge phase performed for memory cells that are smaller in size relative to a reference position of the channel may have a longer precharge period than memory cells that are larger in size relative to the reference position.

The auxiliary power supply 4230 may be connected to the host 4100 through the power connector 4002. The auxiliary power supply 4230 may be supplied with a supply voltage from the host 4100, and may be charged. The auxiliary power supply 4230 may provide the supply voltage of the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located on a main board, and may provide auxiliary power to the SSD 4200.

The buffer memory 4240 functions as a buffer memory of the SSD 4200. For example, the buffer memory 4240 may temporarily store data received from the host 4100 or data received from the plurality of memory devices 4221 to 422n or may temporarily store metadata (e.g., mapping tables) of the memory devices 4221 to 422n. The buffer memory 4240 may include volatile memories, such as DRAM, SDRAM, DDR SDRAM, and LPDDR SDRAM, or nonvolatile memories, such as FRAM, ReRAM, STT-MRAM, and PRAM.

According to the present disclosure, disturbance may be prevented during a program operation of a memory device, and the time required for a program operation may be shortened.

While the present invention has been described with respect to the specific embodiments, it will be apparent to those skilled in the art that various changes and modifications may be made without departing from the spirit and scope of the invention as defined in the following claims. The embodiments may be combined to form additional embodiments.

What is claimed is:

1. A memory device comprising:
a memory block including:
a first selection line, word lines, and a second selection line that are stacked between a source line and bit lines,
a channel layer penetrating the first selection line, the word lines, and the second selection line,
first select transistors connected to the first selection line,
second select transistors connected to the second selection line, and
memory cells connected to the word lines, wherein the first select transistors, the second select transistors, and the memory cells are stacked along the channel layer;
a voltage generator configured to generate a turn-on voltage and a turn-off voltage to be applied to the first and second selection lines, and generate a program voltage and a pass voltage to be applied to the word lines;
a source line driver configured to generate a precharge voltage to be applied to the source line;
a page buffer group configured to apply a program-enable voltage and a program-inhibit voltage to the bit lines; and
a control circuit configured to:
determine a reference position for distinguishing a first area from a second area of the memory block, the first area including word lines coupled to memory cells that may be affected by a disturbance, and the second area including word lines coupled to memory cells that may not be affected by the disturbance in the memory block, and
control the voltage generator, the source line driver, and the page buffer group to adjust a time required to precharge the channel layer depending on a result of a comparison between a position of a selected word line among the word lines and the reference position during a program operation performed for a memory cell that is coupled to the selected word line on the memory block.

2. The memory device according to claim 1, wherein the control circuit is configured to:
when the selected word line is located above the reference position, control the voltage generator, the source line driver, and the page buffer group to precharge the channel layer during a first time, and
when the selected word line is located below the reference position, control the voltage generator, the source line driver, and the page buffer group to precharge the channel layer during a second time shorter than the first time.

3. The memory device according to claim 1, wherein the control circuit is configured to:
set word lines in the second area, including memory cells having a relatively large size, to a first group with respect to the reference position, and
set word lines in the first area, including memory cells having a relatively small size, to a second group with respect to the reference position.

4. The memory device according to claim 3, wherein the control circuit is configured to:
when the selected word line is included in the first group, control the voltage generator, the source line driver, and the page buffer group to precharge the channel layer during a first time, and
when the selected word line is included in the second group, control the voltage generator, the source line driver, and the page buffer group to precharge the channel layer during a second time shorter than the first time.

5. The memory device according to claim 1, wherein the control circuit is configured to control the source line driver to apply the precharge voltage to the source line to precharge the channel layer.

6. The memory device according to claim 5, wherein the voltage generator is configured to, when the precharge voltage is applied to the source line, apply the turn-on voltage to the first selection line under control of the control circuit.

7. The memory device according to claim 6, wherein a time to precharge the channel layer is a period from a time point at which the turn-on voltage starts to be applied to the first selection line to a time point at which the turn-off voltage starts to be applied to the first selection line.

8. The memory device according to claim 7, wherein the voltage generator is configured to apply the turn-off voltage to the second selection line under control of the control circuit while the channel layer is being precharged.

9. The memory device according to claim 1, wherein the control circuit is configured to control the page buffer group to apply the precharge voltage to the bit line to precharge the channel layer.

10. The memory device according to claim 9, wherein the voltage generator is configured to, when the precharge voltage is applied to the bit line, apply the turn-on voltage to the second selection line under control of the control circuit.

11. The memory device according to claim 10, wherein a time to precharge the channel layer is a period from a time point at which the turn-on voltage starts to be applied to the second selection line to a time point at which the program-enable voltage or the program-inhibit voltage starts to be applied to the bit lines.

12. The memory device according to claim 9, wherein the voltage generator is configured to apply the turn-off voltage to the first selection line under control of the control circuit while the channel layer is being precharged.

13. The memory device according to claim 1, wherein the voltage generator comprises:
a first selection line driver configured to generate the turn-on voltage and the turn-off voltage to be applied to the first selection line under control of the control circuit;
a second selection line driver configured to generate the turn-on voltage and the turn-off voltage to be applied to the second selection line under control of the control circuit; and
a word line driver configured to generate the program voltage and the pass voltage to be applied to the word lines under control of the control circuit.

14. The memory device according to claim 1, wherein the control circuit is configured to control the voltage generator to apply the pass voltage to the word lines after precharging of the channel layer is terminated.

15. A method of operating a memory device, comprising:
dividing a plurality of word lines stacked between a source line and bit lines into a first group and a second group depending on a width of a plug penetrating the word lines, wherein the width of the plug corresponding to word lines included in the second group is smaller than the width of the plug corresponding to word lines included in the first group;
precharging a channel layer included in the plug;
after precharging the channel layer, applying a pass voltage to the word lines; and
after the pass voltage is applied to the word lines, applying a program voltage to a selected word line from among the word lines, wherein:
when the selected word line is included in the second group, precharging the channel layer is performed during a first time, and
when the selected word line is included in the first group, precharging the channel layer is performed during a second time shorter than the first time.

16. The method according to claim 15, wherein precharging the channel layer comprises:
applying a precharge voltage to the source line; and
electrically connecting the source line to the channel layer.

17. The method according to claim 16, wherein the precharge voltage is set to a positive voltage greater than zero (0).

18. The method according to claim 16, wherein the source line and the channel layer are connected to each other by turning on first select transistors disposed between the source line and the channel layer.

19. The method according to claim 16, wherein a time during which the source line and the channel layer are electrically connected to each other is set to a first time or a second time.

20. The method according to claim 16, wherein second select transistors disposed between the bit lines and the channel layer are turned off while the channel layer is being precharged.

21. The method according to claim 15, wherein precharging the channel layer comprises:
applying a precharge voltage to the bit lines; and
electrically connecting the bit lines and the channel layer to each other.

22. The method according to claim 21, wherein the bit lines and the channel layer are connected to each other by turning on second select transistors disposed between the bit lines and the channel layer.+

23. The method according to claim 21, wherein a time during which the bit lines and the channel layer are electrically connected to each other is set to a first time or a second time.

24. The method according to claim 21, wherein first select transistors disposed between the source line and the channel layer are turned off while the channel layer is being precharged.

25. The method according to claim 15, wherein applying the pass voltage to the word lines comprises selectively applying a program-enable voltage and a program-inhibit voltage to the bit lines.

26. A method for operating a semiconductor device, comprising:
providing a memory device including a channel passing through a first word line and a second word line;
selecting the first word line;
determining a position of the first word line relative to a reference position of the channel;
precharging the channel for a first time period when the position of the first word line is above the reference position;
selecting the second word line;
determining a position of the second word line relative to the reference position of the channel; and
precharging the channel for a second time period when the position of the second word line is below the reference position,
wherein a top of the channel has a first width and a bottom of the channel has a second width less than the first width, with the reference position being between the top and bottom, and wherein the second time period is longer than the first time period.

27. The method of claim 26, wherein:
a first memory cell coupled to the first word line has a first size, and
a second memory cell coupled to the second word line has a second size less than the first size.

28. The method of claim 26, wherein precharging the channel for the second time period prevents a disturbance from occurring in an unselected memory cell during a program operation performed for a selected memory cell.

29. The method of claim 28, wherein the disturbance includes a change in a threshold voltage of the unselected memory cell.
